(19) United States
(12) Patent Application Publication
(10) Pub. No.: US 2023/0299042 A1
(43) Pub. Date: Sep. 21, 2023

(54) Memory Device and Method of Forming The Same

(71) Applicant: Taiwan Semiconductor Manufacturing Company, Ltd., Hsin-Chu (TW)

(72) Inventors: Yi-Hsuan Chen, Taoyuan City (TW); Kuen-Yi Chen, Hsinchu City (TW); Yi Ching Ong, Hsinchu (TW); KUO-CHING Huang, Hsinchu City (TW); HARRY-HAK-LAY CHUANG, Hsinchu (TW); Yu-Sheng Chen, Hsinchu (TW)

(21) Appl. No.: 17/815,861

(22) Filed: Jul. 28, 2022

Related U.S. Application Data
(60) Provisional application No. 63/321,149, filed on Mar. 18, 2022.

(51) Int. Cl. H01L 23/00; H01L 25/065; H01L 25/18; H01L 25/00

(52) U.S. Cl. CPC H01L 24/80; H01L 25/0657; H01L 25/18; H01L 24/08; H01L 25/50; H01L 2224/08145; H01L 2224/80895; H01L 2224/80896; H01L 2924/1431; H01L 2924/1441

(57) ABSTRACT

A method according to the present disclosure includes forming a plurality of transistors in a first wafer and forming a memory array in a second wafer. A first surface of the first wafer includes a first plurality of bonding pads electrically coupled to the transistors. The memory array includes a plurality of ferroelectric tunnel junction (FTJ) stacks. A second surface of the second wafer includes a second plurality of bonding pads electrically coupled to the FTJ stacks. The method also includes performing a thermal treatment to the FTJ stacks in the second wafer, and after the performing of the thermal treatment, bonding the first surface of the first wafer with the second surface of the second wafer. The transistors are coupled to the memory cells through the first plurality of bonding pads and the second plurality of bonding pads.

### PRIORITY DATA

This application claims the benefit of U.S. Provisional Application No. 63/321,149, filed Mar. 18, 2022, which is hereby incorporated by reference in its entirety.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

The scaling down process has prompted circuit designers to move devices from the front-end-of-line (FEOL) level to the back-end-of-line (BEOL) level where the interconnect structure resides. For example, ferroelectric-based memory devices may be formed at the BEOL level. Forming dielectric-based memory devices at the BEOL level is not without challenges. While existing processes and structures of dielectric-based memory devices are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a diagram of a memory system, according to various aspects of the present disclosure.

FIGS. 2 and 3 are schematic diagrams of some embodiments of a memory cell comprising a selector, according to various aspects of the present disclosure.

FIGS. 4 and 5 are schematic views of some embodiments of a memory array comprising a plurality of memory cells, where the memory cells comprise selectors, according to various aspects of the present disclosure.

FIGS. 6 and 7 respectively illustrate exemplary integrated circuit components and semiconductor devices including bonded integrated circuit components according to exemplary embodiments of the present disclosure.

FIGS. 8, 9, and 10 illustrate exemplary semiconductor wafers including the exemplary integrated circuit components according to exemplary embodiments of the present disclosure.

FIG. 11 illustrate a cross-sectional view of a first device structure comprising transistors and FEOL structures of a memory device, according to various aspects of the present disclosure.

FIG. 12 illustrate a cross-sectional view of a second device structure comprising memory cells of a memory device, according to various aspects of the present disclosure.

FIG. 13 illustrate a cross-sectional view of a memory device after the first and second device structures are bonded together, according to various aspects of the present disclosure.

### DETAILED DESCRIPTION

The present disclosure relates generally to manufacturing memory devices, and more particularly, to manufacturing logic devices and memory array in separate wafers and bonding the separate wafers together by wafer-on-wafer process.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

IC manufacturing process flow is typically divided into three categories: front-end-of-line (FEOL) processes, middle-end-of-line (MEOL) process, and back-end-of-line (BEOL) processes. FEOL processes generally encompass processes related to fabricating IC devices, such as transistors. For example, FEOL processes can include forming isolation features, channel features, gate structures, and source and drain features (generally referred to as source/drain features). MEOL processes generally encompass processes related to fabricating contacts to multi-gate devices, such as fin-type field effect transistors (FinFETs) or gate-all-around (GAA) transistors (also known as multi-bridge-channel (MBC) transistors or surrounding gate transistors (SGTs)). Example MEOL features include contacts to the gate structures and/or the source/drain features of a multi-gate transistor. BEOL processes generally encompass processes related to fabricating a multilayer interconnect (MLI) feature that interconnects FEOL IC features, thereby enabling operation of the IC devices. To save real estate at the FEOL level, larger devices that do not require the level of photolithographic precisions for transistors may be moved to FEOL structures. For example, memory devices, such as magnetic-based memory devices (e.g., magnetic tunnel junction (MTJ) memory devices) and ferroelectric-based memory devices (e.g., ferroelectric tunnel junction (FTJ) memory devices), may be fabricated at the BEOL level.

A ferroelectric-based memory device (or ferroelectric memory device) is a nonvolatile memory (i.e., a memory that can store data in the absence of power). A ferroelectric memory device, such as a ferroelectric field effect transistor (FeFET), a ferroelectric random-access memory (FeRAM or FRAM) device, or a ferroelectric tunnel junction (FTJ) memory device, typically has a ferroelectric film (also referred to as ferroelectric layer) sandwiched between a bottom electrode and a top electrode. An interfacial layer, also referred to as a non-polarization layer, naturally appears between the ferroelectric film and one of the neighboring electrode due to reaction with the metal component of the electrode. The formation of the non-polarization layer is important to create remnant polarization, on which the ferroelectric memory device relies for proper functioning. In an FeRAM, a thick ferroelectric film is sandwiched between two electrodes and the remnant polarization is switched by applying an electric field between the two electrodes. Although the thick ferroelectric film makes it relatively easy to form a non-polarization layer, the readout current across the thick ferroelectric film tends to be low, which creates challenges for miniaturization or integration into the BEOL structures. On the other hand, an FTJ memory includes a thin ferroelectric layer (measured in nanometers) which allows quantum-mechanical tunneling. However, when the ferroelectric film gets thinner (e.g., less than 5 nm), the formation of non-polarization layer becomes difficult and the polarization property of the ferroelectric film starts to disappear, which leads to malfunction of the memory device.

It has been observed that sufficient thermal treatment of the ferroelectric film in ferroelectric memory devices is necessary to achieve crystallization and good ferroelectricity. In some existing technologies, the thermal treatment of the ferroelectric layer is proceeded with caution as excessive heat may cause deterioration of FEOL structures, such as the gate structure. Oftentimes the temperature of the thermal treatment is kept below 400° C., which may cause insufficient crystallization of the ferroelectric film.

The present disclosure provides a process and a ferroelectric memory device (e.g., an FTJ memory structure) to achieve crystallization of the ferroelectric layer without causing unintended damages to the FEOL structures. The ferroelectric memory device of the present disclosure uses a wafer-on-wafer process to fabricate logic device (usually formed in FEOL) and ferroelectric memory device (including ferroelectric film) (usually formed in MEOL or BEOL) separately to overcome thermal constraint and prevent high temperatures affecting elements in the logic device. By WOW technique, no thermal limitation is in the ferroelectric film, as FEOL structures are in a different wafer and not subject to the thermal treatment of the wafer that the ferroelectric film is located. The wafer that hosts the ferroelectric film can be subject to a thermal treatment with a temperature between about 400° C. and about 1000° C. without subjecting the FEOL structures to excessive heat. Thus, the crystallization quality of the ferroelectric film is increased, and the performance of the ferroelectric memory devices is improved with little or no risk of damaging the FEOL structure. Though out the present disclosure, embodiments based on FTJ memory device are given for illustration purpose. The illustrated FTJ memory device is, of course, merely an example and is not intended to be limiting. As discussed above, a ferroelectric film that supports ferroelectric memory applications can be applied to FeFET memory devices, FeRAM memory devices, or FTJ memory devices. Further, many other modern-day electronic devices including electronic memory may also benefit from the wafer-on-wafer process by treating the MEOL/BEOL structures separately from the FEOL structures. Examples of next generation electronic memory include resistive random-access memory (RRAM), phase-change random-access memory (PCRAM), and magneto-resistive random-access memory (MRAM).

The various aspects of the present disclosure will now be described in more detail with reference to the figures. Throughout the present disclosure, unless expressly otherwise described, like reference numerals denote like features.

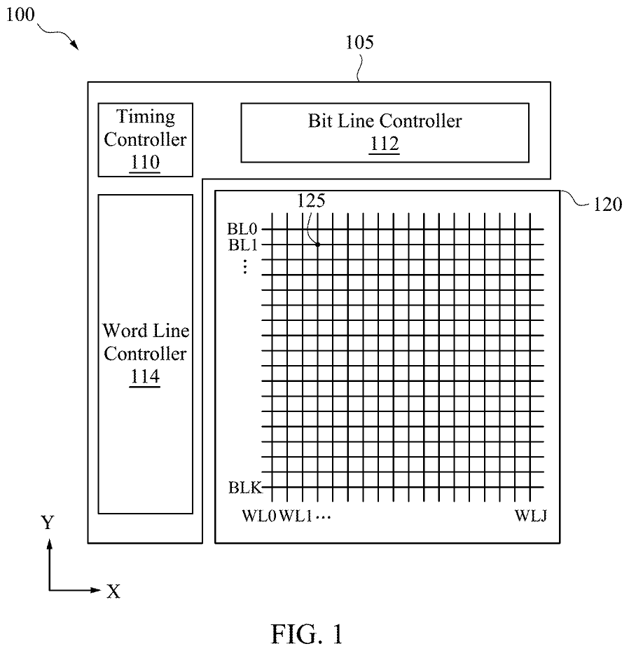

FIG. 1 is a diagram of a memory system 100, in accordance with some embodiments. The memory system 100 includes a memory controller 105 and a memory array 120. The memory array 120 is a hardware component that stores data. In one aspect, the memory array 120 is embodied as a semiconductor memory device. The memory array 120 includes a plurality of storage circuits or memory cells 125. The memory cells 125 may be arranged in two- or three-dimensional arrays. The memory array 120 also includes bit lines BL0, BL1 . . . BLK, each extending in a first direction (e.g., X-direction) and word lines WL0, WL1 . . . WLJ, each extending in a second direction (e.g., Y-direction). The word lines WL and the bit lines BL may be conductive metals or conductive rails. In one aspect, each memory cell 125 is coupled to a corresponding word line WL and a corresponding bit line BL, and can be operated according to voltages or currents through the corresponding word line WL and the corresponding bit line BL. Each memory cell 125 may be coupled to a corresponding word line WL and a corresponding bit line BL. Since memory cells 125 are arranged at cross points of BLs and WLs, such a memory system 100 is also referred to as a cross-point memory architecture.

A cross-point memory array may, for example, comprise multiple one-selector one-FTJ (1S1F) memory cells respectively arranged at cross points of bit lines and source lines. The selector is configured to pass current when biased above respective threshold voltages. By appropriately biasing a bit line and a source line, a 1S1F memory cell at a cross point of the bit line and the source line can be selected and written to opposite states. When a 1S1F memory cell is selected, other bit lines and source lines may be biased at a middle point voltage to turn off unselected memory cells. Without a selector, the collective leakage current flowing through unselected memory cells introduces disturbance and reduces the current window for memory operation for reading and writing operations. The disturbance may even result in a reading failure during the reading operation or a false writing during the writing operation. A cross-point memory architecture with 1S1F memory cells may also achieve high density, as several 1S1F memory cells may share one transistor, without a need of a cross-coupled transistor for each memory cell.

The memory controller 105 may write data to or read data from the memory array 120 according to electrical signals through word lines WL and bit lines BL. In other embodiments, the memory system 100 includes more, fewer, or different components than shown in FIG. 1. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line controller 112, a word line controller 114, and a timing controller 110. In one configuration, the word line controller 114 is a circuit that provides a voltage or a current through one or more word lines WL of the memory array 120, and the bit line controller 112 is a circuit that provides or senses a voltage or current through one or more bit lines BL of the memory array 120. In one configuration, the timing controller 110 is a circuit that provides control signals or clock signals to synchronize operations of the bit line controller 112 and the word line controller 114. The bit line controller 112 may be coupled to bit lines BL of the memory array 120, and the word line controller 114 may be coupled to word lines WL of the memory array 120. In one example, to write data to a memory cell 125, the word line controller 114 provides a voltage or current to the memory cell 125 through a word line WL coupled to the memory cell 125, and the bit line controller 112 applies a bias voltage to the memory cell 125 through a bit line BL coupled to the memory cell 125. In one example, to read data from a memory cell 125, the word line controller 114 provides a voltage or current to the memory cell 125 through a word line WL coupled to the memory cell 125, and the bit line controller 112 senses a voltage or current corresponding to data stored by the memory cell 125 through a bit line BL coupled to the memory cell 125. In some embodiments, the memory controller 105 includes more, fewer, or different components than shown in FIG. 1.

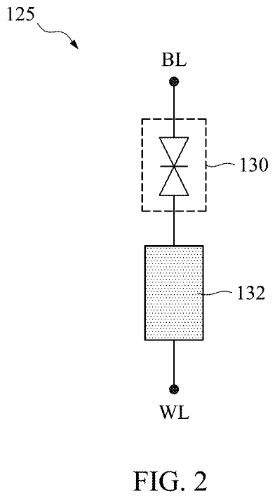

FIG. 2 illustrates an example memory cell 125 as a building block of the memory array 120 as shown in FIG. 1. Particularly, FIG. 2 illustrates a one-selector one-FTJ (1S1F) memory cell comprising a selector 130 electrically coupled in series with a data-storage element 132, from a bit line BL to a word line WL. In some embodiments, locations of the bit line BL and the word line WL are reversed. In some embodiments, locations of the selector 130 and the data-storage element 132 are reversed.

The selector 130 is configured to selectively allow current to flow in a first direction from a bit line BL to a word line WL, while blocking the flow of current in a second direction from the word line WL to the bit line BL. The selector 130 can be a unipolar selector or a bipolar selector. A unipolar selector switches at a single polarity whereas a bipolar selector switches at two polarities. At a first polarity, the selector conducts and/or is in a low resistance state called “on” state if the voltage across the unipolar selector exceeds a threshold voltage. Otherwise, at the first polarity, the unipolar selector is non-conducting or is in a high resistance state called “off” state. At the second polarity, the selector is in the “off” state. In some embodiments, the selector 130 has only two terminals. In some alternative embodiments, the selector 130 has more than two terminals. The selector 130 may, for example, be PIN diodes, polysilicon diodes, punch-through diodes, varistor-type selectors, ovonic threshold switches (OTSs), doped-chalcogenide-based selectors, Mott effect based selectors, mixed-ionic-electronic-conductive (MIEC)-based selectors, field-assisted-superliner-threshold (FAST) selectors, filament-based selectors, doped-hafnium-oxide-based selectors, or some other suitable diodes and/or selectors.

An example of the operation is as follows: when the voltage across the selector 130 is positive from the bit line BL to the data-storage element 132, the selector 130 conducts and is in a low resistance state if the voltage across the selector 130, from the bit line BL to the data-storage element 132, exceeds a threshold voltage Vt. Otherwise, the selector 130 is non-conducting and/or is in a high resistance state. The data-storage element 132 stores a bit of data. As an example, during the writing operation, a writing voltage is applied such that the selector 130 is biased above the threshold voltage at the first polarity and the data-storage element 132 is set to a first data state. During the reading operation, a reading voltage is applied such that the selector 130 is biased above the threshold voltage at the first polarity while the data-storage element 132 is not altered. The reading voltage may be smaller than the writing voltage.

In some embodiments, a resistance of the data-storage element 132 varies depending upon a data state of the data-storage element. For example, the data-storage element 132 may have a low resistance at a first data state and may have a high resistance at a second data state. In other embodiments, capacitance or some other suitable parameter of the data-storage element 132 varies depending upon a data state of the data-storage element 132. In some embodiments, the data-storage element 132 is a metal-insulator-metal (MIM) stack, and the memory cell 125 may be a resistance memory cell. In furtherance of the embodiments, the data-storage element 132 is a ferroelectric tunnel junction (FTJ) or a magnetic tunnel junction (MTJ). Other structures for the data-storage element 132 and/or other memory-cell types for the memory cell 125 are also amenable.

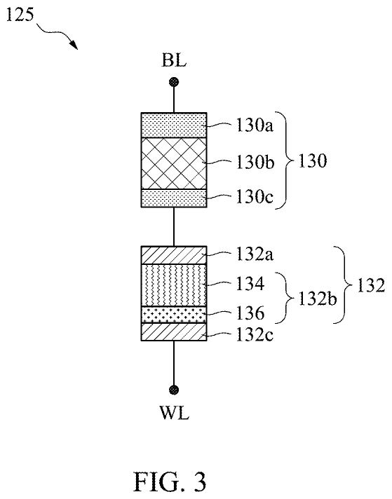

With reference to FIG. 3, a schematic diagram of some more detailed embodiments of the memory cell 125 of FIG. 2 is provided in which the selector 130 is a multilayer stack, such as a PIN diode or a metal-insulator-metal (MIM) stack. The selector 130 comprises a cathode 130a (or a top electrode 130a), an insulator 130b, and an anode 130c (or a bottom electrode 130c). The insulator 130b is sandwiched between the cathode 130a and the anode 130c. In some embodiments, the anode 130c is directly connected to the data-storage element 132, meaning the anode 130c is electrically connected to the data-storage element 132 by one or more conductive wires and/or vias without other electronic devices disposed therebetween. In some alternative embodiments, the selector 130 may be reversely placed that the cathode 130a is directly connected to the data-storage element 132. In some embodiments in which the multilayer stack is a PIN diode, the cathode 130a is or comprises N-type semiconductor material, the anode 130c is or comprises P-type semiconductor material, and the insulator 130b is or comprises intrinsic or lightly doped semiconductor material. The insulator 130b may, for example, be lightly doped relative to the cathode 130a and/or the anode 130c. The semiconductor material of the multilayer stacks may, for example, be or comprises polysilicon, monocrystalline silicon, germanium, indium gallium arsenide, or some other suitable semiconductor material. In some embodiments in which the multilayer stack is a MIM device, the cathode 130a and the anode 130b are or comprise metal or some other suitable conductive material (e.g., Al, Cu, Ag, Pt, etc.) and/or the insulator 130b is or comprises a high-k dielectric material, such as HfO₂, Ta₂O₅, TaOₓ (x≤2.5), TiO₂, some other suitable metal oxide, or doped or suitable combinations of the dielectrics (e.g., a combination of Ta₂O₅, TaOₓ, or a combination of Ta₂O₅, TaOₓ, and TiO₂). Alternatively, the insulator 130b is or comprises a semiconductor material, such as a Te-based and/or Se-based material, including SiTe, GeSE, and/or SiSe.

In some embodiments, a thickness of the insulator 130b is varied to adjust the threshold voltage of the selector 130. For example, increasing a thickness of an insulator may increase a threshold voltage of the corresponding selector whereas decreasing the thickness may decrease the threshold voltage. In some embodiments, a doping concentration of the insulator 130b is varied to adjust the threshold voltage of the selector 130. For example, increasing a doping concentration of an insulator may decrease a threshold voltage of the corresponding selector whereas decreasing the doping concentration may increase the threshold voltage. In some embodiments, a width of the unipolar selector 104 is varied to adjust an “on” resistance of the unipolar selector 104. For example, increasing a width of a selector may decrease an “on” resistance of the selector whereas decreasing the width may increase the “on” resistance.

Still referring to FIG. 3, the depicted data-storage element 132 is a ferroelectric stack 132, in portion or entirety, according to various aspects of the present disclosure. The ferroelectric stack 132 includes a ferroelectric switching layer (FSL) 132b (i.e., including multiple layers) disposed between a top electrode 132a and a bottom electrode 132c. In some embodiments, the top electrode 132a and the bottom electrode 132c are both metal, and the ferroelectric stack 132 is also referred to as a metal-ferroelectric switching layer (FSL)-metal (MFM) stack. In some embodiments, the ferroelectric stack 132 provides an FTJ. An FTJ includes a thin ferroelectric layer (measured in nanometers) which allows quantum-mechanical tunneling. The quantum-mechanical tunneling gives rise to tunnel electroresistance with highly discernible ON/OFF resistances.

The top electrode 132a physically contacts a top surface of the FSL 132b, and the bottom electrode 132c physically contacts a bottom surface of the FSL 132b, in the depicted embodiment. Each of the top electrode 132a and the bottom electrode 132c may be a metal layer, a metal-nitride layer, a metal-oxide layer, or a semiconductor layer. In one example, the top and bottom electrodes may include Al, Ti, Ta, Au, Pt, W, Ni, Ir, other suitable metal, alloys thereof (e.g., TaN, TiN, and/or other suitable alloy), or combinations thereof. In another example, the top and bottom electrodes may include a metal oxide, such as IrO₂. In yet another example, the top and bottom electrodes may include polysilicon (n-type doped or p-type doped).

The FSL 132b includes at least a layer of ferroelectric material, which generally refers to a material that exhibits polarization upon application of an electric field thereto and continues to exhibit polarization upon removal (or reduction) of the electric field. Accordingly, the ferroelectric material is also known as polarization material. Generally, the ferroelectric material has intrinsic electric dipoles that can be switched between polarization states by the electric field, such as between a first polarization state and a second polarization state. The first polarization state can correspond with a first data state, such as a logical “1” (e.g., a first resistance or a first capacitance depending on the ferroelectric memory device). The second polarization state can correspond with a second data state, such as a logical “0” (e.g., a second resistance or a second capacitance depending on the ferroelectric memory device).

The FSL 132b includes a ferroelectric layer 134 having a characteristic of ferroelectricity. The ferroelectric layer 134 includes a ferroelectric material (polarization material). The ferroelectric layer 134 is also referred to as a polarization layer. The ferroelectric layer 134 may be a single layer or a multi-layer structure, such as a first ferroelectric layer disposed over a second ferroelectric layer, wherein the first ferroelectric layer and the second ferroelectric layer have different compositions. The ferroelectric material can be a high-k dielectric material, such as a dielectric material having a dielectric constant (k) greater than about 28 (e.g., k≥28), having an orthorhombic crystal structure. In some embodiments, the ferroelectric layer 134 includes a metal oxide material or a metal oxynitride material. For example, the ferroelectric layer 134 may include a hafnium oxide-based material or a zirconium oxide-based material. In furtherance of the example, the ferroelectric layer 134 can include hafnium oxide (e.g., HfₓO_{y}), hafnium zirconium oxide (e.g., HfₓZr_{z}O_{y})(also referred to as HZO), hafnium aluminum oxide (e.g., HfₓAl_{z}O_{y}), hafnium lanthanum oxide (e.g., HfₓLa_{z}O_{y}), hafnium cerium oxide (e.g., HfₓCe_{z}O_{y}), hafnium silicon oxide (HfₓSiO_{y}), hafnium gadolinium oxide (e.g., HfₓGd_{z}O_{y}), other suitable HfₓO_{y}-based material, or combinations thereof, where x, y, z are atom percentages. In another example, the ferroelectric layer 134 can include a ZrⱼOₖ-based material, where j, k, z are atom percentages. In some embodiments, a thickness of the ferroelectric layer 134 is less than about 5 nm.

The FSL 132b further includes a dielectric layer 136 sandwiched between the ferroelectric layer 134 and the bottom electrode 132c. Alternatively, the dielectric layer 136 may be sandwiched between the ferroelectric layer 134 and the top electrode 132a. The dielectric layer 136 includes a non-polarization material. The dielectric layer 136 is also referred to as a non-polarization layer. In some embodiments, the dielectric layer 136 includes a dielectric material having a dielectric constant (k) smaller than about 28 (e.g., k<28). The value of the dielectric constant is not trivial. One function of the dielectric layer 22 is to create different resistance and thus different read currents corresponding to different polarization orientations of the ferroelectric layer 20. If the dielectric constant is larger than about 28, the read current may become too small to detect. The dielectric material can include a material having different crystalline characteristics and/or different crystalline conditions than a material of ferroelectric layer 134. For example, where ferroelectric layer 134 includes a dielectric material having a crystalline structure, the dielectric layer 136 incudes a dielectric material having an amorphous structure (e.g., dielectric material in non-crystalline form (i.e., having a disordered atomic structure)). The dielectric layer 136 has an amorphous structure to inhibit any additional crystalline growth and/or grain growth in the ferroelectric layer 134 that can lead to crystal phase changes that cause undesired ferroelectric changes in the ferroelectric layer 134. In some embodiments, the dielectric layer 136 includes a metal oxide material that is different than a metal oxide material of the ferroelectric layer 134. For example, the dielectric layer 136 includes AlₓO_{y}, SiₓO_{y}, TaₓO_{y}, TiₓO_{y}, LaₓO_{y}, YₓO_{y}, SrₓTiO_{z}, or combinations thereof, where x, y, z are atom percentages. In one example, the dielectric layer 136 includes SiₓN_{y}. A thickness of the dielectric layer 136 may be less than about 2 nm. The thickness is not trivial. If the thickness of the dielectric layer 136 is larger than about 2 nm, the read current may become too small to be sensed, and/or differences between logical states may become too small to be discerned. In some embodiments, a thickness of the FSL 132b is smaller than a thickness of the insulator 130b of the selector 130.

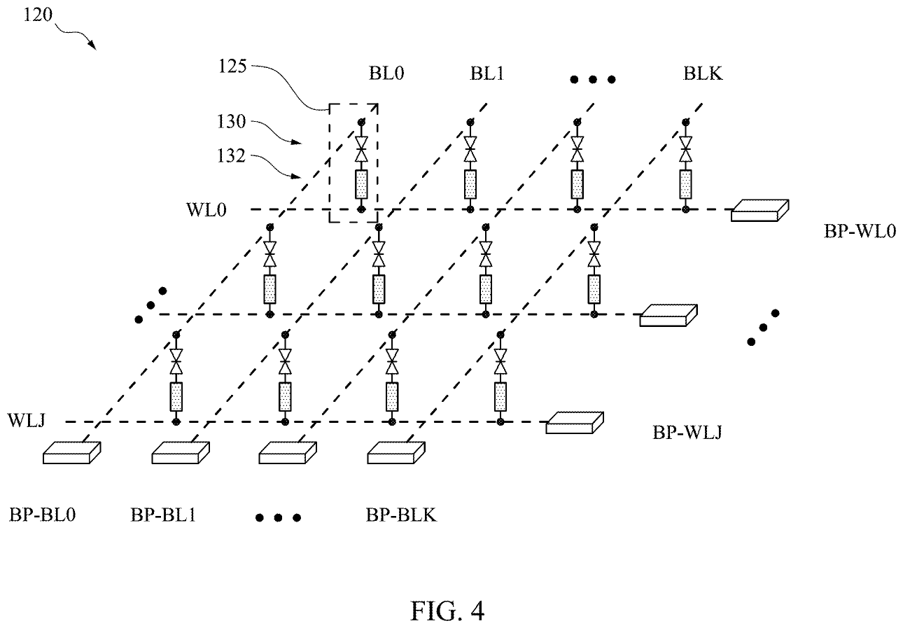

With reference to FIG. 4, a schematic view of some embodiments of a memory array 120 comprising a plurality of memory cells 125 in a plurality of rows and a plurality of columns is provided. The memory cells 125 respectively comprises the selector 130 electrically coupled in series with the data-storage elements 132. The memory cells 125 may, for example, each be as illustrated and described with regard to FIGS. 2 and 3. As an example, bit lines (e.g. BL0, BL1 . . . BLK) extend laterally along corresponding columns of the memory array and electrically couple with memory cells in the corresponding columns, whereas word lines (e.g. WL0, WL1 . . . WLJ) extend laterally along corresponding rows of the memory array and electrically couple with memory cells in the corresponding rows. The subscripts identify corresponding rows or columns, and K or J is an integer variable representing a column or a row in the memory array 120. By appropriately biasing a bit line BL and a word line WL, the memory cell at the cross point of the bit line BL and the word line WL may be selected for reading or writing. Each bit line BL is electrically connected to a bonding pad BP (e.g., PBL0, PBL1 . . . PBLK), and each word line WL is electrically connected to a bonding pad BP (e.g., PW0, PW1 . . . PWJ) as well. The bonding pads BP are located in a hybrid bonding layer (or bonding layer) of a wafer to provide connections to transistors (and other FEOL structures) in another wafer.

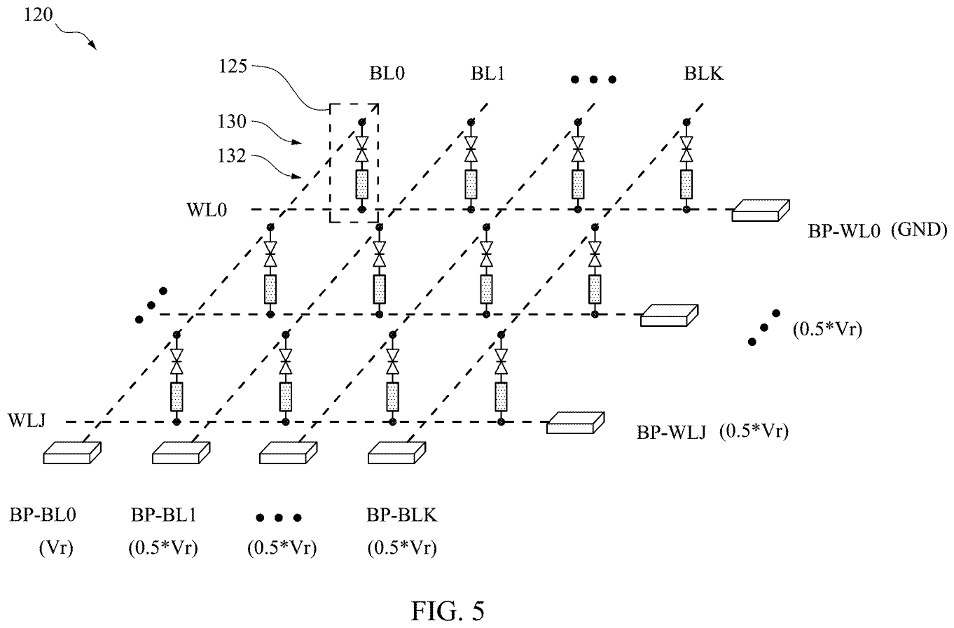

As illustrated by FIG. 5, a selected memory cell 125 is at the cross point of bit line BL0 and word line WL0. The bonding pad BP-BL0 is biased with a read voltage Vr under a reading operation (or a write voltage Vw under a writing operation), while the bonding pad BP-WL0 is grounded. In some embodiments, the other world lines WL and the other bit lines BL biased with half the read voltage Vr or some other fraction (e.g. one third) of the read voltage Vr to reduce read disturbance to unselected memory cells. The read voltage Vr is positive from bit line BL0 to word line WL0 and exceeds a threshold of the selector 130, such that the selector 130 in the selected memory cell 125 is ON. A current flows through the selected memory cell 125 and further flow through a corresponding transistor formed in another wafer through the bonding pads BP, allowing a resistance state of the selected memory cell 125 to be sensed. The selectors 130 in other unselected memory cells 125 are OFF. Accordingly, current does not flow through the unselected memory cells 125 and there is no read disturbance to the unselected memory cells 125.

The selectors 130 allows more than one memory cells 125 to share one transistor without reading collective leakage current flowing through unselected memory cells. For example, each row of the memory cells 125 may correspond to one transistor, or each column of the memory cells 125 may correspond to one transistor. Comparing with assigning one transistor to each memory cell 125, which needs K×J transistors and two times of bonding pads BP (2×K×J), implementing the selectors 130 reduces the amount of transistors needed (e.g., K or J, instead of K×J), as well as the amount of bonding pads BP needed (e.g., K+J, instead of 2×K×J), which significantly saves circuit area and reduces manufacturing costs in return. That is, in some embodiments, a number transistors is lees than a number of bonding pads BP associated with the transistors, and the number of bonding pads BP associated with the transistors is less than a number of memory cells in a memory array that associates with the transistors.

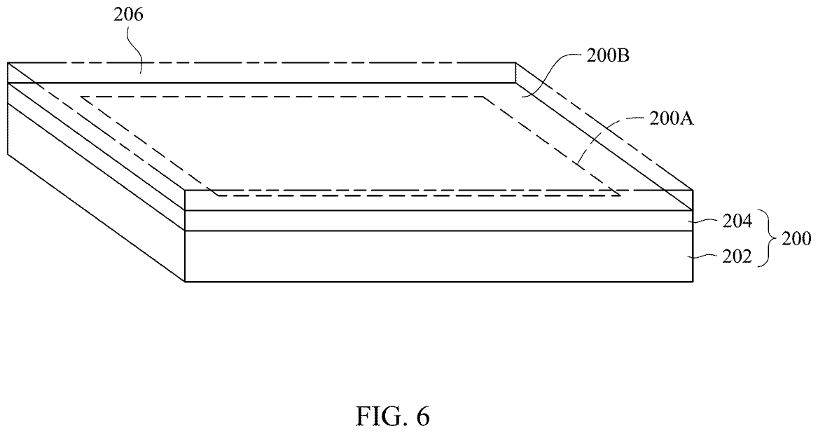

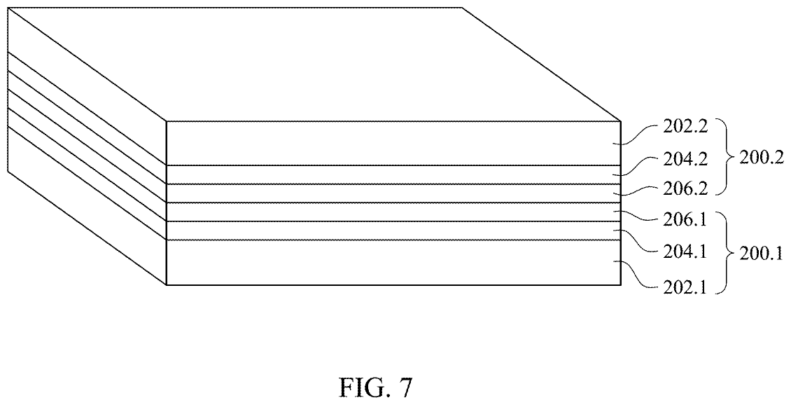

FIGS. 6 and 7 collectively illustrate exemplary bonded integrated circuit components according to exemplary embodiments of the present disclosure. As illustrated in FIG. 6, an exemplary integrated circuit component 200 includes a semiconductor substrate 202 having electronic circuitry formed therein, and an interconnection structure 204 disposed on the semiconductor substrate 202. In some embodiments, the integrated circuit component 200 includes an active region 200A in which the electronic circuitry is formed and a periphery region 200B surrounding the active region 200A. A redistribution layer 206 is fabricated on the interconnection structure 204 of the integrated circuit component 200 in a back-end-of-line (BEOL) process. The redistribution layer 206 formed on the interconnection structure 204 of the integrated circuit component 200 may serve as a bonding layer when the integrated circuit component 200 is bonded with other components. Therefore, the redistribution layer 206 is also referred to as the bonding layer 206. In the exemplary embodiment illustrated in FIG. 6, the electronic circuitry formed in the semiconductor substrate 202 includes analog and/or digital circuitry situated within a semiconductor stack having one or more conductive layers, also referred to as metal layers, interdigitated with one or more non-conductive layers, also referred to as insulation layers. However, one skilled in the relevant art(s) will recognize the electronic circuitry may include one or more mechanical and/or electromechanical devices without departing from the spirit and scope of the present disclosure.

The semiconductor substrate 202 may be made of silicon or other semiconductor materials. Alternatively, the semiconductor substrate 202 may include other elementary semiconductor materials such as germanium. In some embodiments, the semiconductor substrate 202 is made of a compound semiconductor such as sapphire, silicon carbide, gallium arsenic, indium arsenide, or indium phosphide. In some embodiments, the semiconductor substrate 202 is made of an alloy semiconductor such as silicon germanium, silicon germanium carbide, gallium arsenic phosphide, or gallium indium phosphide. In some embodiments, the semiconductor substrate 202 includes an epitaxial layer. For example, the semiconductor substrate 202 has an epitaxial layer overlying a bulk semiconductor.

The semiconductor substrate 202 may further include isolation features (not shown), such as shallow trench isolation (STI) features or local oxidation of silicon (LOCOS) features. Isolation features may define and isolate various semiconductor elements. The semiconductor substrate 202 may further include doped regions (not shown). The doped regions may be doped with p-type dopants, such as boron or BF₂, and/or n-type dopants, such as phosphorus (P) or arsenic (As). The doped regions may be formed directly on the semiconductor substrate 202, in a P-well structure, in an N-well structure, or in a dual-well structure.

The electronic circuitry including the above-mentioned isolation features and semiconductor elements (e.g., transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n channel field effect transistors (PFETs/NFETs), etc.), diodes, and/or other applicable elements) may be formed over the semiconductor substrate 102. Various processes may be performed to form the isolation features and semiconductor elements, such as deposition, etching, implantation, photolithography, annealing, and/or other applicable processes. In some embodiments, the electronic circuitry including the isolation features and semiconductor elements are formed in the semiconductor substrate 202 in a front-end-of-line (FEOL) process.

In some embodiments, the interconnection structure 204 includes dielectric layers, conductive vias embedded in the dielectric layers, and conductive wirings formed between the dielectric layers. Different layers of the conductive wirings are electrically connected to one another through the conductive vias. Furthermore, the interconnection structure 204 is electrically connected to the electronic circuitry formed in the semiconductor substrate 202. In some embodiments, at least one seal ring and at least one alignment mark are formed in the interconnection structure 204, with the seal ring and the alignment mark being formed within the periphery region 200B of the integrated circuit component 200. In some instances, the seal ring surrounds the active region 200A of the integrated circuit component 200, and the alignment mark is formed within a region outside of the seal ring. In some embodiments, pluralities of alignment marks are formed around corners of the integrated circuit component 200. The number of the above-mentioned seal ring and alignment mark(s) is not limited in this disclosure.

In the exemplary embodiment illustrated in FIG. 6, the redistribution layer 206 represents a conductive layer (e.g., a metal layer) from among the one or more conductive layers of the semiconductor stack which is utilized for electrically coupling the electronic circuitry to other electrical, mechanical, and/or electromechanical devices. For example, the redistribution layer 206 may be used to electrically couple the electronic circuitry to an integrated circuit package, such as a through-hole package, a surface mount package, a pin grid array package, a flat package, a small outline package, a chip-scale package, and/or a ball grid array to provide some examples.

As another example and as illustrated in FIG. 7, a semiconductor device includes a first integrated circuit component 200.1, a first redistribution layer 206.1, a second integrated circuit component 200.2 and a second redistribution layer 206.2. The first redistribution layer 206.1 and the second redistribution layer 206.2 are between the first integrated circuit component 200.1 and the second integrated circuit component 200.2. An exemplary first integrated circuit component 100.1 includes a first semiconductor substrate 202.1 having first electronic circuitry formed therein, and a first interconnection structure 204.1 disposed on the first semiconductor substrate 202.1. An exemplary second integrated circuit component 200.2 includes a second semiconductor substrate 202.2 having second electronic circuitry formed therein, and a second interconnection structure 204.2 disposed on the semiconductor substrate 202.2. The first redistribution layer 206.1 from among a first semiconductor stack associated with first electronic circuitry may be electrically and/or mechanically coupled to the second redistribution layer 206.2 from among a second semiconductor stack associated with second electronic circuitry to electrically couple the first electronic circuitry and the second electronic circuitry. In this exemplary embodiment, the first redistribution layer 206.1 is configured and arranged to be electrically and/or mechanically coupled to the second redistribution layer 206.2. In an exemplary embodiment, the first redistribution layer 206.1 is bonded to the second redistribution layer 206.2 using hybrid bonding techniques. In this exemplary embodiment, the hybrid bonding techniques utilize a bonding wave to electrically and/or mechanically couple the first redistribution layer 206.1 and the second redistribution layer 206.2. The term “hybrid bonding” derives from a combination of metal-to-metal bond and insulator-to-insulator (or dielectric-to-dielectric) bond during the bonding process. In some instances, the redistribution layers 206.1 and 206.2 include conducive features for a metal-to-metal bond and dielectric features for an insulator-to-insulator bond, and the bonding wave joins dielectric surfaces that also have metal interconnects to be joined together in the same planar bonding interface. Accordingly, the redistribution layers 206.1 and 206.2 may also be referred to as bonding layers 206.1 and 206.2 (or hybrid bonding layers 206.1 and 206.2). As to be described in further detail below, the first redistribution layer 206.1 and the second redistribution layer 206.2 are configured and arranged to increase balance in bonding wave propagation paths (e.g., along the X-direction and the Y-direction) in promoting symmetric bonding wave propagation between the first redistribution layer 206.1 and the second redistribution layer 206.2 during the bonding, which effectively reduces wafer distortion after the bonding. Notably, those killed in the relevant art(s) would recognize the spirit and scope of the present disclosure can also be applied to other well-known bonding techniques, including but not limiting to direct bonding, surface activated bonding, plasma activated bonding, anodic bonding, eutectic bonding, thermo-compression bonding, reactive bonding, and transient liquid phase diffusion bonding.

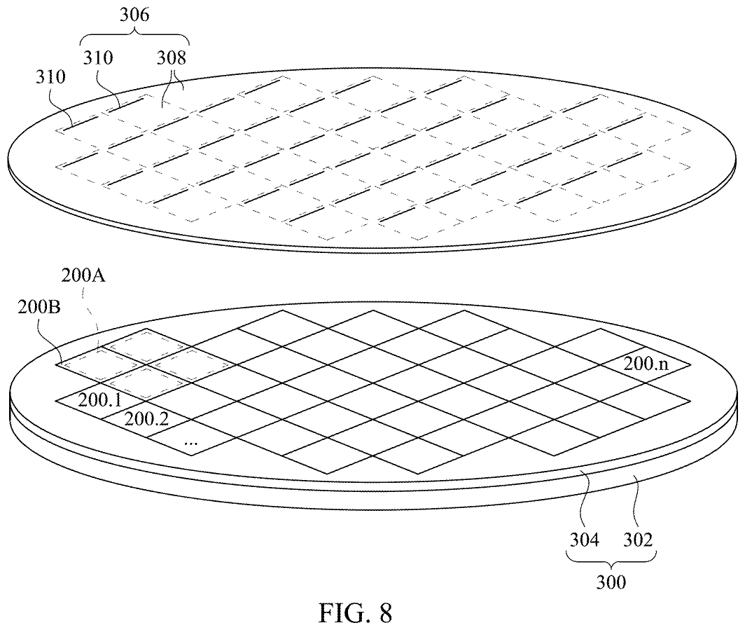

FIGS. 8, 9, and 10 illustrate exemplary semiconductor wafers including the exemplary integrated circuit components according to exemplary embodiments of the present disclosure. Referring to FIG. 8, a semiconductor device fabrication operation is utilized to manufacture multiple integrated circuit components 200.1 through 200.n in a semiconductor wafer 300. The semiconductor wafer 300 includes multiple integrated circuit components 200.1 through 200.n arranged in array. In some embodiments, the semiconductor wafer 300 includes a semiconductor substrate 302 having electronic circuitry formed therein and an interconnection structure 304 disposed on the semiconductor substrate 302. In some embodiments, each one of the integrated circuit component 200.1 through 200.n included in the semiconductor wafer 300 includes an active region 200A having electronic circuitry formed therein and a periphery region 200B surrounding the active region 200A. The semiconductor device fabrication operation uses a predetermined sequence of photographic and chemical processing operations to form the multiple integrated circuit components 200.1 through 200.n in the first semiconductor wafer 300.

In the exemplary embodiment illustrated in FIG. 8, the integrated circuit components 200.1 through 200.n are formed in and/or on the semiconductor substrate 302 using a first series of fabrication operations, referred to as front-end-of-line processing, and a second series of fabrication operations, referred to as back-end-of-line processing. The front-end-of-line processing represents a series of photographic and chemical processing operations to form corresponding electronic circuitry of the multiple integrated circuit components 200.1 through 200.n in and/or on the semiconductor substrate 302. The back-end-of-line processing represents another series of photographic and chemical processing operations to form corresponding interconnection structure 204 of the multiple integrated circuit components 200.1 through 200.n on the semiconductor substrate 302 to form the semiconductor wafer 300. In an exemplary embodiment, the integrated circuit components 200.1 through 200.n included in the semiconductor wafer 300 may be similar and/or dissimilar to one other.

As shown in FIG. 8, the semiconductor substrate 302 is a portion of the semiconductor wafer 300. The semiconductor substrate 302 may be made of silicon or other semiconductor materials. Additionally, the semiconductor substrate 302 may include other elementary semiconductor materials such as germanium. In some embodiments, the semiconductor substrate 302 is made of a compound semiconductor such as silicon carbide, gallium arsenic, indium arsenide, or indium phosphide. In some embodiments, the semiconductor substrate 302 is made of an alloy semiconductor such as sapphire, silicon germanium, silicon germanium carbide, gallium arsenic phosphide, or gallium indium phosphide. In some embodiments, the semiconductor substrate 302 includes an epitaxial layer. For example, the semiconductor substrate 302 has an epitaxial layer overlying a bulk semiconductor. The semiconductor substrate 302 may further include isolation features (not shown), such as shallow trench isolation (STI) features or local oxidation of silicon (LOCOS) features. Isolation features may define and isolate various semiconductor elements. The semiconductor substrate 302 may further include doped regions (not shown). The doped regions may be doped with p-type dopants, such as boron or BF₂, and/or n-type dopants, such as phosphorus (P) or arsenic (As). The doped regions may be formed directly on the semiconductor substrate 302, in a P-well structure, in an N-well structure, or in a dual-well structure.

In some embodiments, the interconnection structure 304 includes dielectric layers, conductive vias embedded in the dielectric layers, and conductive wirings between the dielectric layers, wherein different layers of the conductive wirings are electrically connected to one another through the conductive vias.

A redistribution layer 306 is formed over the semiconductor wafer 300. In some embodiments, the process for fabricating the redistribution layer 306 over the semiconductor wafer 300 includes: forming a dielectric layer over the semiconductor wafer 300; patterning the dielectric layer to form a plurality of openings in the dielectric layer to expose conductive pads of the semiconductor wafer 300; depositing a conductive material over the semiconductor wafer 300 such that the dielectric layer and the conductive pads exposed by the openings in the dielectric layer are covered by the conductive material, wherein the conductive material not only covers the dielectric layer and the conductive pads, but also covers sidewall surfaces of the openings and completely fill the openings; performing a grinding process (e.g., CMP process) to partially remove an excess portion of conductive material until the top surface of the dielectric layer 308 is exposed so as to form arrays of conductive contacts 310 (e.g., metal vias and/or metal pads) in the dielectric layer 308. The redistribution layer 306 including the dielectric layer 308 and the arrays of conductive contacts 310 may serve as a bonding layer when a wafer level bonding process is performed to bond the semiconductor wafer 300 with another wafer.

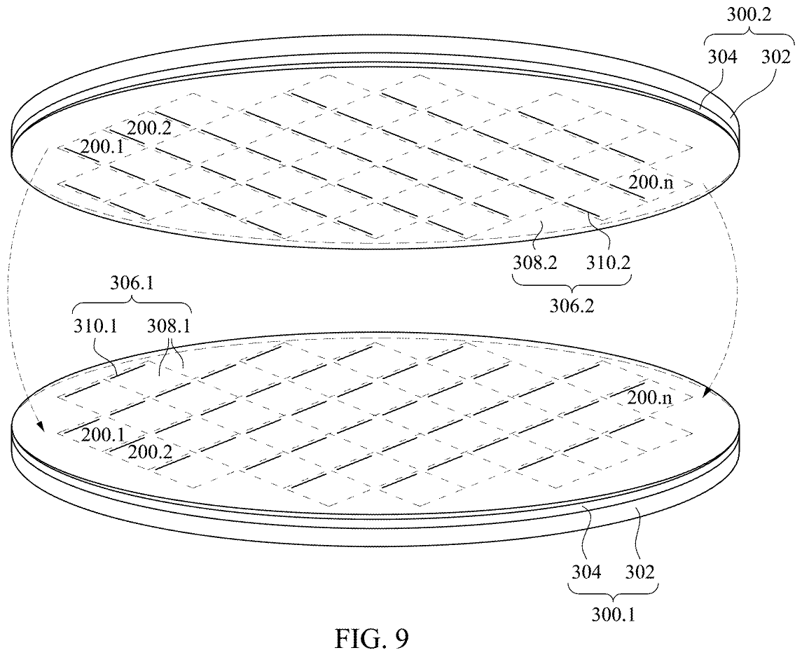

As illustrated in FIG. 9, a first semiconductor wafer 300.1 and a second semiconductor wafer 300.2 to be bonded with each other are provided. In some embodiments, two different types of wafers 300.1 and 300.2 are provided. In other words, the integrated circuit components 200.1 through 200.n included in first semiconductor wafer 300.1 and the integrated circuit components 200.1 through 200.n included in second semiconductor wafer 300.2 may have different architectures and perform different functions. For example, the second semiconductor wafer 300.2 is a memory device wafer including a plurality of chips that include memory arrays (e.g., memory array 120 as in FIG. 3) and other FEOL structures and the first semiconductor wafer 300.1 is an application-specific integrated circuit (ASIC) wafer including a plurality of transistors and other FEOL structures. The transistors in the first semiconductor wafer 300.1 correspond to the memory cells (e.g., memory cells 125 as in FIG. 3) in the memory arrays in the second semiconductor wafer 300.2. In furtherance of the embodiments, the second semiconductor wafer 300.2 is free of transistors, allowing the second semiconductor wafer 300.2 to go through excessive heat to achieve higher crystallization quality for the ferroelectric films in the memory cells.

Before bonding the first semiconductor wafer 300.1 and the second semiconductor wafer 300.2, a first redistribution layer 306.1 and a second redistribution layer 306.2 are formed over the first semiconductor wafer 300.1 and the second semiconductor wafer 300.2 respectively. The process for forming the first redistribution layer 306.1 and the second redistribution layer 306.2 may be similar with the process for forming the redistribution layer 306 illustrated in FIG. 8.

In some embodiments, the process for fabricating the first redistribution layer 306.1 over the first semiconductor wafer 300.1 includes: forming a first dielectric layer over the first semiconductor wafer 300.1; patterning the first dielectric layer to form a plurality of first openings in the first dielectric layer 308.1 to expose first conductive pads of the first semiconductor wafer 300.1; depositing a first conductive material over the first semiconductor wafer 300.1 such that the first dielectric layer 308.1 and the first conductive pads exposed by the first openings in the first dielectric layer 308.1 are covered by the first conductive material, wherein the first conductive material not only covers the first dielectric layer 308.1 and the first conductive pads, but also covers sidewall surfaces of the first openings and completely fill the first openings; performing a first grinding process (e.g., CMP process) to partially remove an excess portion of first conductive material until the top surface of the first dielectric layer 308.1 is exposed so as to form multiple arrays of conductive contacts 310.1 (e.g., bonding pads BP as in FIG. 3) in the first dielectric layer 308.1. In some embodiments, the process for fabricating the second redistribution layer 306.2 over the second semiconductor wafer 300.1 includes: forming a second dielectric layer 306.2 over the second semiconductor wafer 300.2; patterning the second dielectric layer 308.2 to form a plurality of second openings in the second dielectric layer 308.2 to expose second conductive pads of the second semiconductor wafer 300.2; depositing a second conductive material over the second semiconductor wafer 300.2 such that the second dielectric layer 308.2 and the second conductive pads exposed by the second openings are covered by the second conductive material, wherein the second conductive material not only covers the second dielectric layer 308.2 and the second conductive pads, but also covers sidewall surfaces of the second openings and completely fill the second openings; performing a second grinding process (e.g., CMP process) to partially remove an excess portion of second conductive material until the top surface of the second dielectric layer 308.2 is exposed so as to form multiple arrays of conductive contacts 310.2 (e.g., bonding pads BP as in FIG. 3) in the second dielectric layer 308.2.

In some embodiments, the arrays of conductive contacts 310.1 slightly protrude from the top surface of the first dielectric layer 308.1 and the arrays of conductive contacts 310.2 slightly protrude from the top surface of the second dielectric layer 308.2 because the first and dielectric layers 308.1 and 308.2 are polished at a relatively higher polishing rate while the conductive material is polished at a relatively lower polishing rate during the CMP processes.

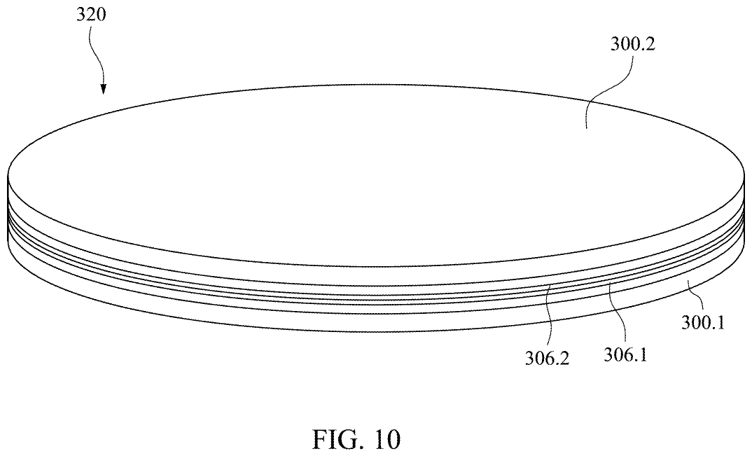

As illustrated in FIGS. 9 and 10, after the first and second redistribution layers 306.1 and 306.2 are formed over the first and second semiconductor wafers 300.1 and 300.2, the second semiconductor wafer 300.2 having the second redistribution layer 306.2 formed thereon is flipped onto the first redistribution layer 306.1 formed on the first semiconductor wafer 300.1 such that the multiple arrays of conductive contacts 310.1 of the first redistribution layer 306.1 are substantially aligned with the multiple arrays of conductive contacts 310.2 of the second redistribution layer 206.2. Then, the first semiconductor wafer 300.1 is bonded to the second semiconductor wafer 300.2 through the first and second redistribution layers 306.1 and 306.2 to form a semiconductor device 320. In some embodiments, the bonding interface between the first redistribution layer 306.1 and the second redistribution layer 306.2 in the bonded structure (e.g., the semiconductor device) 320 is substantially misalignment free after performing the bonding process. This bonding may include hybrid bonding, direct bonding, surface activated bonding, plasma activated bonding, anodic bonding, eutectic bonding, thermo-compression bonding, reactive bonding, transient liquid phase diffusion bonding and/or any other well-known bonding technique which is apparent to those skilled in the relevant art(s) without departing from the spirit and scope of the present disclosure. Subsequently, the bonded structure 320 is diced into individual chips.

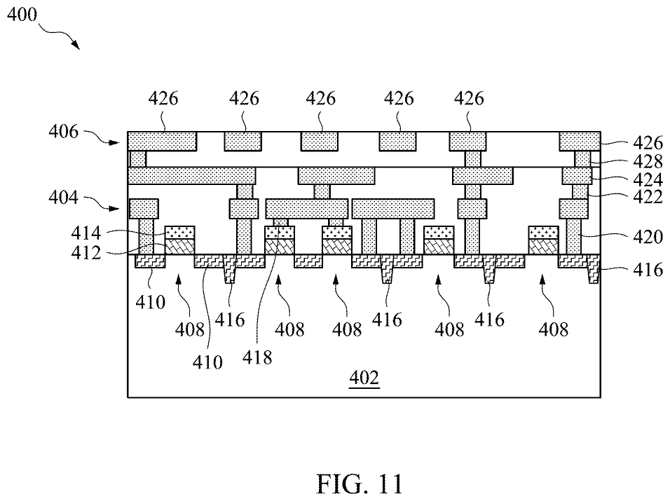

FIG. 11 illustrates a fragmentary cross-sectional view of a device structure 400. The device structure 400 is simplified and not all features in the device structure 400 are illustrated or described in detail. The device structure 400 shown in the figures together with the device structure 500 as discussed later may be a portion of an IC chip, a system on chip (SoC), or portion thereof, that may include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In furtherance of some embodiments, the device structure 400 is a portion of the first integrated circuit component 200.1 (FIGS. 6 and 7).

The device structure 400 includes an interconnect structure 404 overlying a substrate 402. In an embodiment, the substrate 402 includes silicon (Si). Alternatively or additionally, substrate 402 may include another elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 402 may be a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. The substrate 402 can include various doped regions (not shown) depending on design requirements of device structure 200. In some implementations, the substrate 402 includes p-type doped regions (for example, p-type wells) doped with p-type dopants, such as boron (for example, BF₂), indium, other p-type dopant, or combinations thereof. In some implementations, the substrate 402 includes n-type doped regions (for example, n-type wells) doped with n-type dopants, such as phosphorus (P), arsenic (As), other n-type dopant, or combinations thereof. In some implementations, the substrate 402 includes doped regions formed with a combination of p-type dopants and n-type dopants. The various doped regions can be formed directly on and/or in the substrate 402, for example, providing a p-well structure, an n-well structure, a dual-well structure, a raised structure, or combinations thereof. An ion implantation process, a diffusion process, and/or other suitable doping process can be performed to form the various doped regions.

A plurality of semiconductor devices 408 are disposed within and/or over the substrate 402. In some embodiments, the semiconductor devices 408 may, for example, be configured as transistors or as another suitable semiconductor device. In such embodiments, the semiconductor devices 408 may include corresponding source/drain regions 410, corresponding gate structures 412, and corresponding gate capping layers 414. As used herein, a source/drain region, or “S/D region,” may refer to a source or a drain of a device. It may also refer to a region that provides a source and/or drain for multiple devices. In some embodiments, the source/drain regions 410 are disposed within the substrate 402 and may comprise a second doping type (e.g., n-type) opposite the first doping type (e.g., p-type). In further embodiments, the gate structures 412 may include corresponding gate electrodes overlying corresponding gate dielectric layer. In various embodiments, the gate electrodes may, for example, be or comprise a metal (such as aluminum, tungsten, titanium, any combination of the foregoing, or the like), polysilicon, another suitable conductive material, or any combination of the foregoing. In further embodiments, the gate dielectric layers may, for example, be or comprise silicon dioxide, a high-k dielectric material, another suitable dielectric material, or any combination of the foregoing. The gate capping layers 414 are conductive and may, for example, be or comprise tantalum, titanium, a silicide, another suitable material, or any combination of the foregoing. Further, isolation structures 416 are disposed within the substrate 402 and may laterally surround a corresponding semiconductor device 408. In some embodiments, the isolation structures 416 may, for example, be configured as shallow trench isolation (STI) structures, deep trench isolation (DTI) structures, or another suitable isolation structure. In further embodiments, the isolation structures 416 may, for example, be or comprise silicon dioxide, silicon nitride, silicon carbide, another suitable dielectric material, or any combination of the foregoing.

Further, the semiconductor devices 408 may be a planar transistor or a multi-gate transistor, such as a fin-like FET (FinFET) or a gate-all-around (GAA) transistor. A GAA transistor may include channel regions of various shapes including nanowire, nanobar, or nanosheet, which may be collectively referred to as nanostructures. A GAA transistor may also be referred to as a multi-bridge-channel (MBC) transistor or a surrounding-gate-transistor (SGT). While the semiconductor devices 408 is shown as a planar device in FIG. 11 and subsequent figures, it should be understood that the semiconductor devices 408 may as well be a FinFET or a GAA transistor.

The interconnect structure 404 includes a lower portion that includes gate contact vias 418 and source/drain contact vias 420 embedded in an interlayer dielectric (ILD) layer. The ILD layers may include silicon oxide, tetraethylortho silicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. The source/drain contact may include ruthenium (Ru), cobalt (Co), nickel (Ni), or copper (Cu). The gate contact via may include tungsten (W), ruthenium (Ru), cobalt (Co), nickel (Ni), or copper (Cu). The interconnect structure 404 includes an upper portion including multiple metal layers sequentially stack, such as a first metal layer M₁ to an nth metal layer Mₙ (not shown). Further metal layers of the interconnect structure 404 will be formed over the nth metal layer Mₙ. In some embodiments, the interconnect structure 404 may include about two (2) to about five (5) metal layers. Each of the metal layers of the interconnect structures include multiple vias and metal lines embedded in at least one intermetal dielectric (IMD) layer. The vias and metal lines may be formed of titanium (Ti), ruthenium (Ru), nickel (Ni), cobalt (Co), copper (Cu), molybdenum (Mo), tungsten (W), or aluminum (Al). In one embodiment, they are formed of copper (Cu). The IMD layer may have a composition similar to that of the ILD layers described above. The vias 422 and metal lines 424 are embedded or disposed in the IMD layers.

The device structure 400 includes a redistribution layer (or hybrid bonding layer) 406 disposed over the interconnect structure 404. The redistribution layer 406 includes conductive features (e.g., bonding pads 426) for a metal-to-metal bond, and dielectric features for insulator-to-insulator bond. The bonding pads 426 electrically connect to the transistors 408 through vias 428 embedded in the redistribution layer 406 and the metal wiring in the interconnect structure 404.

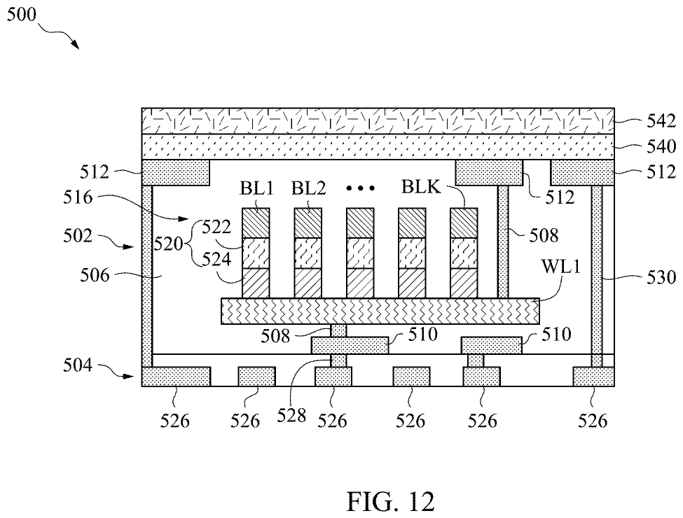

FIG. 12 illustrates a fragmentary cross-sectional view of a device structure 500. The device structure 500 is simplified and not all features in the device structure 500 are illustrated or described in detail. The device structure 500 shown in the figures together with the device structure 400 as bonded together may be a portion of an IC chip, a system on chip (SoC), or portion thereof, that may include various passive and active microelectronic devices such as resistors, capacitors, inductors, diodes, other suitable components, or combinations thereof. In furtherance of some embodiments, the device structure 500 is a portion of the second integrated circuit component 200.2 (FIG. 7). Still further, the device structure 500 includes a memory array, such as an FTJ array.

The device structure 500 includes an interconnect structure 502 overlying a redistribution layer 504. In some embodiments, the interconnect structure 502 may include about two (2) to about eight (8) metal layers. Each of the metal layers of the interconnect structures include multiple vias and metal lines embedded in at least one intermetal dielectric (IMD) layer 506. The vias and metal lines may be formed of titanium (Ti), ruthenium (Ru), nickel (Ni), cobalt (Co), copper (Cu), molybdenum (Mo), tungsten (W), or aluminum (Al). In one embodiment, they are formed of copper (Cu). The IMD layer 506 may be or comprise an oxide, such as silicon dioxide, a low-k dielectric material, another suitable dielectric material, or any combination of the foregoing. In yet further embodiments, the IMD layer 506 may, for example, be or comprise silicon dioxide, a low-k dielectric material, silicon nitride, silicon carbide, extreme low k (ELK) dielectric material, another suitable dielectric material, or any combination thereof. The vias 508 and metal lines 510 are embedded or disposed in the IMD layers. Further, upper conductive wires 512 overlie the vias 508 and metal lines 510.

The device structure 500 includes a memory array 516 comprising a plurality of memory cells 520 stacked between a plurality of bit lines BLs (e.g., BL1, BL2 . . . BLK) and a plurality of word lines WLs (e.g., WL1, WL2 . . . WLK). In various embodiments, the memory cells 520 are arranged in an array having a plurality of rows and a plurality of columns. In some embodiments, an individual word line WL and an individual bit line BL are coupled to each individual memory cell. In further embodiments, respective word lines WLs are coupled to respective rows of memory cells 520. In yet further embodiments, respective bit lines BLs are coupled to respective columns of memory cells 520.

In some embodiments, a memory cell 520 includes a data-storage element 522 overlying a selector 524. The data-storage element 522 is configured to store data and may be a non-volatile memory cell or a volatile memory cell. In some embodiments, the data-storage element 522 may be a resistive switching memory cell (e.g., resistive random-access memory (RRAM) cell, phase-change random-access memory (PCRAM) cell, metal-cation RRAM, etc.) configured to store data based on a resistive state of a data storage structure. For example, the data storage structure may have a high resistance state associated with a first data state (e.g., binary “0”) or a low resistance state associated with a second data state (e.g., binary “1”). In some embodiments, the data storage structure may comprise an MTJ. In some embodiments, the data storage structure may comprise an FTJ. In addition, the selector 524 is configured to switch between a low resistance state and a high resistance state depending on a voltage applied across the selector 524. For example, the selector 524 may be in a high resistance state if a voltage applied across the selector 524 is less than the threshold voltage, and the selector 524 may have a low resistance state if a voltage across the selector 524 is greater than the threshold voltage. The locations of the data-storage element 522 and the selector 524 can be switched.

The device structure 500 includes a redistribution layer (or hybrid bonding layer) 504 disposed under the interconnect structure 502. The redistribution layer 504 includes conductive features (e.g., bonding pads 526) for a metal-to-metal bond, and dielectric features for insulator-to-insulator bond. The bonding pads 526 electrically connect to the bit lines BLs and word lines WLs of the memory array 516 through vias 528 embedded in the redistribution layer 504 and the metal wiring in the interconnect structure 502. Through-substrate-vias (TSV) 530 connects some of the bonding pads 526 to some of the upper conductive wires 512. Further, in the depicted embodiment, vias 508 connect word lines WLs to some of the upper conductive wires 512. In various embodiments, the passivation layers 540, 542 may, for example, respectively be or comprise silicon dioxide, silicon oxynitride, silicon oxycarbide, silicon nitride, silicon carbide, another suitable dielectric material, or any combination of the foregoing.

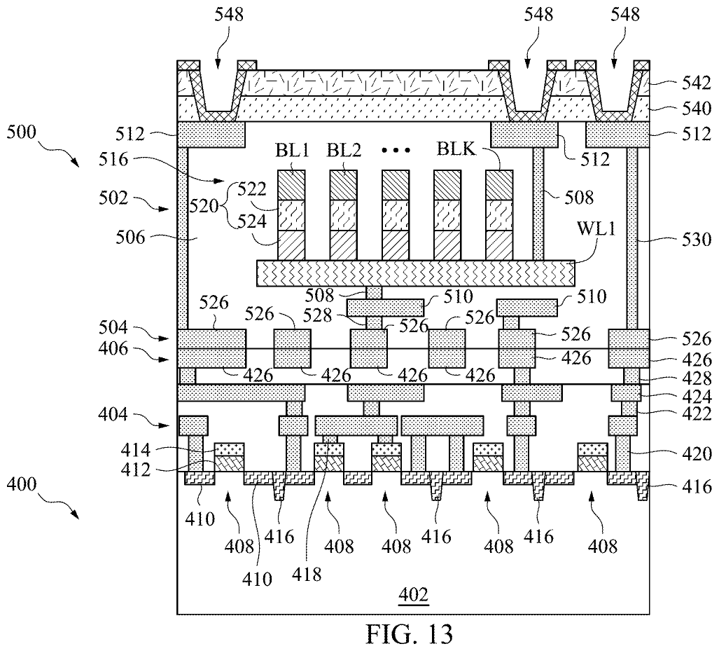

By forming transistors and other FEOL structures in one wafer and memory cells in another wafer, excessive thermal temperature can be applied to the memory cells without causing damage to the transistors and other FEOL structures. After the thermal treatment, the two wafers are bonded together by using a wafer-on-wafer technique. FIG. 13 illustrates the bonded structure after the device structures 400 and 500 are bonded together. Bond pads 548 are subsequently disposed within the first passivation layer 542 and overlie corresponding upper conductive wires 512. Further, since sizes of the bonding pads are usually much larger than sizes of transistors and memory cells, a traditional one-to-one mapping of the bonding pads and individual memory cells translates to the same number of bonding pads as the memory cells (K×K) in the memory array, which would cost a large device area and render the wafer-on-wafer technique impractical. The selectors in the memory cells allows a row or a column of the memory cells to share one transistor, thus the number of transistors and the number of bonding pads needed are significantly reduced, making wafer-on-wafer memory structure feasible. In some embodiments, each of the bit lines BLs and word lines WLs is associated with one bonding pads, instead of each memory cell. Similarly, multiple memory cells can share a same transistor. The number of transistors is also reduced.

In one exemplary aspect, the present disclosure is directed to a method. The method includes forming a plurality of transistors in a first wafer, a first surface of the first wafer including a first plurality of bonding pads electrically coupled to the transistors, forming a memory array in a second wafer, the memory array including a plurality of ferroelectric tunnel junction (FTJ) stacks, and a second surface of the second wafer including a second plurality of bonding pads electrically coupled to the FTJ stacks, performing a thermal treatment to the FTJ stacks in the second wafer, and after the performing of the thermal treatment, bonding the first surface of the first wafer with the second surface of the second wafer, such that the transistors are coupled to the memory cells through the first plurality of bonding pads and the second plurality of bonding pads. In some embodiments, at least some of the second plurality of bonding pads are coupled to signal lines of the memory array. In some embodiments, the signal lines include word lines and bit lines of the memory array. In some embodiments, each of the signal lines of the memory array is coupled to at least one of the second plurality of bonding pads. In some embodiments, the second wafer is free of transistors. In some embodiments, among the transistors coupled to the memory cells, each of the transistors is associated with multiple FTJ stacks in the memory array. In some embodiments, each of the FTJ stacks is coupled to a selector. In some embodiments, the selector is formed in the second wafer. In some embodiments, the selector includes a metal-insulator-metal structure. In some embodiments, the thermal treatment comprises a temperature between about 400° C. and about 1000° C.

In another exemplary aspect, the present disclosure is directed to a method. The method includes forming a plurality of transistors in a first wafer, forming a first redistribution layer on the first wafer, the first redistribution layer including a first plurality of bonding pads that are associated with the plurality of transistors, forming a plurality of memory cells in a second wafer, forming a second redistribution layer on the second wafer, the second redistribution layer including a second plurality of bonding pads that are associated with the plurality of memory cells, performing a thermal treatment to the plurality of memory cells in the second wafer to increase a crystallization quality of the memory cells, and after the performing of the thermal treatment, bonding the second wafer to the first wafer, each of the first plurality of bonding pads being bonded to a corresponding one in the second plurality of bonding pads. In some embodiments, the memory cells are sandwiched between top signal lines and bottom signal lines, and each of the top and bottom signal lines is associated with one of the second plurality of bonding pads. In some embodiments, each of the memory cells includes a selector electrically coupled to a ferroelectric film. In some embodiments, the ferroelectric film has a thickness less than about 5 nm. In some embodiments, a number of the plurality of transistors is less than a number of the first plurality of bonding pads. In some embodiments, a number of the second plurality of bonding pads is less than a number of the memory cells.

In yet another exemplary aspect, the present disclosure is directed to a method. The method includes forming a plurality of transistors in a first wafer, forming a first interconnect structure coupled to the transistors, forming a first redistribution layer coupled to the first interconnect structure, forming a memory array in a second wafer, the memory array including a plurality of ferroelectric tunnel junction (FTJ) stacks, forming a second interconnect structure coupled to the memory array, forming a second redistribution layer coupled to the second interconnect structure, performing a thermal treatment to the second wafer to increase a crystallization quality of ferroelectric films in the FTJ stacks, and after the performing of the thermal treatment, bonding the second wafer to the first wafer, such that the transistors are coupled to the memory array through the first interconnect structure, the first redistribution layer, the second redistribution layer, and the second interconnect structure. In some embodiments, the memory array includes a plurality of selectors coupled to the FTJ stacks. In some embodiments, a number of the selectors equals a number of the FTJ stacks. In some embodiments, at least one of the transistors is coupled to more than one of the FTJ stacks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of transistors in a first wafer, wherein a first surface of the first wafer includes a first plurality of bonding pads electrically coupled to the transistors;
forming a memory array in a second wafer, wherein the memory array includes a plurality of ferroelectric tunnel junction (FTJ) stacks, and wherein a second surface of the second wafer includes a second plurality of bonding pads electrically coupled to the FTJ stacks;
performing a thermal treatment to the FTJ stacks in the second wafer; and
after the performing of the thermal treatment, bonding the first surface of the first wafer with the second surface of the second wafer, such that the transistors are coupled to the memory cells through the first plurality of bonding pads and the second plurality of bonding pads.

2. The method of claim 1, wherein at least some of the second plurality of bonding pads are coupled to signal lines of the memory array.

3. The method of claim 2, wherein the signal lines include word lines and bit lines of the memory array.

4. The method of claim 2, wherein each of the signal lines of the memory array is coupled to at least one of the second plurality of bonding pads.

5. The method of claim 1, wherein the second wafer is free of transistors.

6. The method of claim 1, wherein among the transistors coupled to the memory cells, each of the transistors is associated with multiple FTJ stacks in the memory array.

7. The method of claim 1, wherein each of the FTJ stacks is coupled to a selector.

8. The method of claim 7, wherein the selector is formed in the second wafer.

9. The method of claim 7, wherein the selector includes a metal-insulator-metal structure.

10. The method of claim 1, wherein the thermal treatment comprises a temperature between about 400° C. and about 1000° C.

11. A method, comprising:
forming a plurality of transistors in a first wafer;
forming a first redistribution layer on the first wafer, wherein the first redistribution layer includes a first plurality of bonding pads that are associated with the plurality of transistors;
forming a plurality of memory cells in a second wafer;
forming a second redistribution layer on the second wafer, wherein the second redistribution layer includes a second plurality of bonding pads that are associated with the plurality of memory cells;
performing a thermal treatment to the plurality of memory cells in the second wafer to increase a crystallization quality of the memory cells; and
after the performing of the thermal treatment, bonding the second wafer to the first wafer, wherein each of the first plurality of bonding pads is bonded to a corresponding one in the second plurality of bonding pads.

12. The method of claim 11, wherein the memory cells are sandwiched between top signal lines and bottom signal lines, and each of the top and bottom signal lines is associated with one of the second plurality of bonding pads.

13. The method of claim 11, wherein each of the memory cells includes a selector electrically coupled to a ferroelectric film.

14. The method of claim 13, wherein the ferroelectric film has a thickness less than about 5 nm.

15. The method of claim 11, wherein a number of the plurality of transistors is less than a number of the first plurality of bonding pads.

16. The method of claim 15, wherein a number of the second plurality of bonding pads is less than a number of the memory cells.

17. A method, comprising:
forming a plurality of transistors in a first wafer;
forming a first interconnect structure coupled to the transistors;
forming a first redistribution layer coupled to the first interconnect structure;
forming a memory array in a second wafer, wherein the memory array includes a plurality of ferroelectric tunnel junction (FTJ) stacks;
forming a second interconnect structure coupled to the memory array;
forming a second redistribution layer coupled to the second interconnect structure;
performing a thermal treatment to the second wafer to increase a crystallization quality of ferroelectric films in the FTJ stacks; and
after the performing of the thermal treatment, bonding the second wafer to the first wafer, such that the transistors are coupled to the memory array through the first interconnect structure, the first redistribution layer, the second redistribution layer, and the second interconnect structure.

18. The method of claim 17, wherein the memory array includes a plurality of selectors coupled to the FTJ stacks.

19. The method of claim 18, wherein a number of the selectors equals a number of the FTJ stacks.

20. The method of claim 17, wherein at least one of the transistors is coupled to more than one of the FTJ stacks.
